(19) United States
(12) Patent Application Publication
(10) Pub. No.: US 2006/0255377 A1
(43) Pub. Date: Nov. 16, 2006

(54) Field effect transistor with novel field-plate structure

(76) Inventor: Der-Wei Tu, Tao Yuan Shien (TW)

Correspondence Address: LOWE HAUPTMAN BERNER, LLP, 1700 DIAGONAL ROAD, SUITE 300, ALEXANDRIA, VA, 22314, US

(21) Appl. No.: 11/127,228

(22) Filed: May 12, 2005

(51) Int. Cl. H01L 31/112; H01L 29/80

(52) U.S. Cl. 257/280

(57) ABSTRACT

A field effect transistor (FET) with novel field-plate structure relates to a Schottky gate FET structure with field plate thereon for increasing the operation voltage. The structure can eliminate surface damages of unpassivated region and degradation of the interface property of gate contacts during plasma etching of dielectric film for gate recesses, and can be reliably used in wireless and satellite communications.

### BACKGROUND OF THE INVENTION

1. Field of the Invention

The present invention relates to a field-effect transistor (FET), more particularly, relates to a Schottky gate FET structure with field plate thereon for increasing the operation voltage, which can be reliably used in wireless and satellite communications.

2. Description of the Prior Art

High-power and high-speed semiconductor device operating at microwave frequency is the key component used in wireless and satellite communications. Compound semiconductor Schottky gate FETs, such as GaAs metal-semiconductor FETs (MESFET), high electron mobility transistor (HEMT) as well as pseudomorphic HEMT (p-HEMT), are well known devices for such applications. For a conventional Schottky gate FET, a metal electrode is directly contacted to the semiconductor, forming a Schottky gate junction. When a voltage is applied to the Schottky junction of the gate electrode, the current flow from drain to source electrodes through the channel region will be modified due to the variation of carrier density therein caused by the applied gate voltage. As a result, applying a modulation voltage or a control voltage to the gate electrode will enable a FET functioning as an amplifier or a switch. However, when the Schottky gate junction is biased at higher voltages, a region of huge electric field will be formed in the channel underneath the gate electrode, particularly in the vicinity of the drain edge. Such a large electric field will lead to an avalanche breakdown in the channel region between the gate and the drain electrodes, and therefore induce a large leakage current through the channel. This problem is particularly important for large-signal and high-output operations since the device performance is obviously limited by the breakdown voltage and the leakage current. To achieve high output-power, high-efficiency, and/or high-voltage operations for a transistor, it is essential to have high breakdown voltage associated with high confidence level of reliability.

A straightforward method to increase the breakdown voltage of a Schottky gate FET is to increase the distance between the gate and the drain electrodes so that both the electric field strength and the leakage current can be effectively reduced. However, larger gate-drain distance will also lead to larger source-drain resistance, which in effect reduces the maximum output current and hence the maximum output power from the device.

In order to sustain a Schottky gate FET under high-voltage operation, a “double-recess” structure has been proposed to increase the breakdown voltage, which is also the most commonly used approach to enhance the device operation voltage. FIG. 1 shows the cross-section view of a typical double-recess Schottky gate FET. It has been proven that a device of double-recess structure shows high breakdown voltage with high reliability. However, the drawback of this approach is that a device of high breakdown voltage tends to suffer from a significant gate-lag. Consequently, even with high breakdown voltage, it is difficult to achieve high output power using the double-recess approach.

Another way to achieve high voltage operation for a Schottky gate FET is the use of a field plate on the gate region. FIG. 2 shows a typical Schottky gate FET structure with a dielectric-assisted field-plate gate electrode. The field plate region 12 in FIG. 2 is isolated from the junction by a thin dielectric film 11, so that the electric field centralizing on the edge of gate region can be effectively suppressed. The field-plate approach has been widely used in Si industry to improve the breakdown voltage of metal-oxide semiconductor (MOS) FETs. For GaAs-based power FETs, it has also been demonstrated that excellent performance in both breakdown voltage and output power by using dielectric-assisted gates as shown in FIG. 2. For this approach, it is worth mentioning that the gate electrode has to be formed after the deposition of dielectric film and the plasma etching of gate recesses. However, it is difficult to control plasma damage during the gate recess undercut, which inevitably degrades the interface property of the gate contact as well as the surface of the unpassivated region. Consequently, the device reliability suffers frequently.

### SUMMARY OF THE INVENTION

Accordingly, it is an objective of the present invention to provide a novel Schottky gate FET structure with a field plate thereon, which makes the device to have a high breakdown voltage with a high confidence level of reliability.

It is also an objective of the present invention to provide a novel Schottky gate FET structure with a field plate thereon being capable of high-frequency and high-output-power operations.

Another and more specific objective of the present invention is to provide a novel Schottky gate FET structure with a field plate thereon that can eliminate surface damages of unpassivated region and degradation of the interface property of gate contacts during plasma etching of dielectric film for gate recesses.

In order to achieve the objectives, the field effect transistor according to the present invention comprises:

a semiconductor substrate and a channel layer thereon; a contact layer forming a source region, a drain region with a distance apart from said source region and a recess region being formed by removing part of said contact layer between said source and said drain regions; a source electrode being formed on said source region, making an ohmic contact with said contact layer and being electrically coupled to said channel layer underneath; a drain electrode being formed on said drain region, making an ohmic contact with said contact layer and being electrically coupled to said channel layer underneath; a gate electrode having a finger shape, being formed on said recess region of said contact layer, and forming a Schottky contact with said channel layer underneath; a dielectric film overlaying the region between said source electrode and drain electrode, including said gate electrode finger; and an electrically conductive field plate being disposed on said dielectric film right above said gate electrode finger.

### BRIEF DESCRIPTION OF DRAWINGS

FIG. 1 is a cross-section view of a conventional typical Schottky gate FET with double-recess structure.

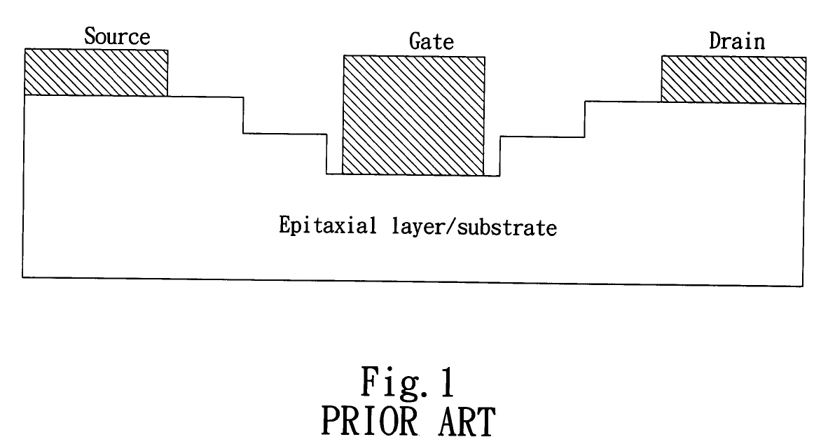

FIG. 2 is a conventional typical Schottky gate FET structure with a dielectric-assisted field-plate gate electrode; and

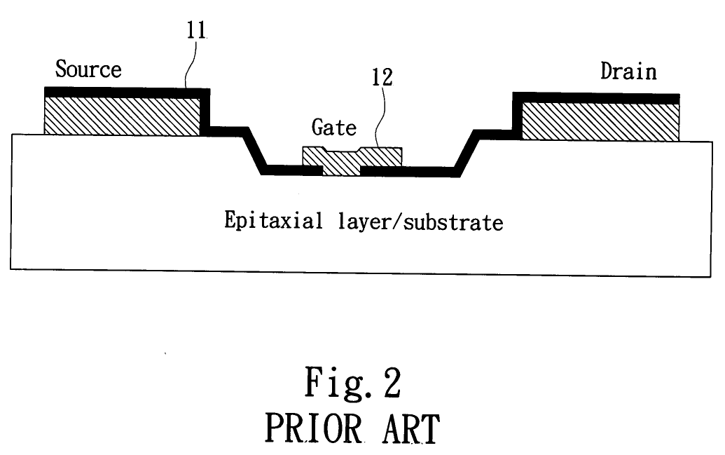

FIG. 3 illustrates a cross-section view of the novel Schottky gate FET structure with a field plate thereon of the present invention.

### DETAILED DESCRIPTION OF THE INVENTION

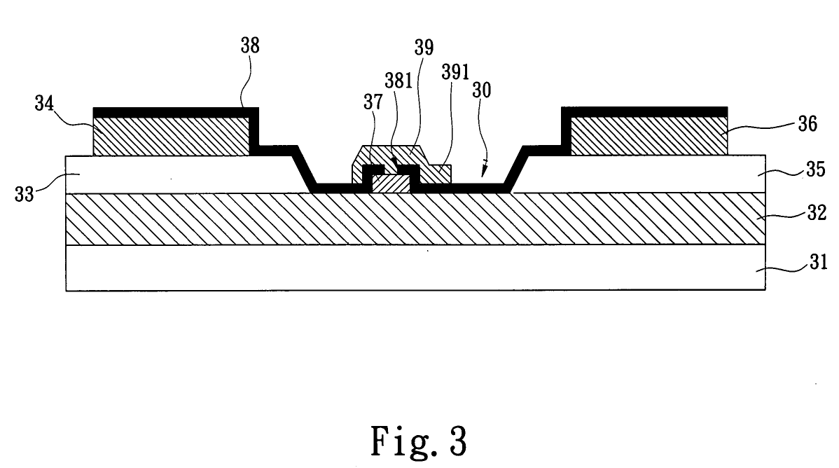

FIG. 3 is a cross-section view of the novel Schottky gate FET structure with a field plate thereon of the present invention. The semiconductor layer structure in FIG. 3 generally comprises a substrate 31 and a channel layer 32 thereon, whereon a contact layer is formed. The contact layer has a source region 33, a drain region 35 with a distance apart from the source region 33 and a recess region 30 being formed by removing the part of the contact layer between the source and the drain regions 33, 35. A source electrode 34 and a drain electrode 36 are formed on the source region 33 and the drain region 35, respectively. Both the source and the drain electrodes 34, 36 make an ohmic contact with the contact layer, and being electrically coupled to the channel layer 32 underneath. On the recess region 30 of the contact layer, a gate electrode 37, having a finger shape, is formed and making a Schottky contact with the channel layer 32 underneath. After the formation of the source, drain and gate electrodes 34, 36, 37, a dielectric film 38 is overlaid for surface passivation, which covers the recess region 30 of the contact layer, including the gate electrode 37 finger thereon. On the dielectric film 38, an electrically conductive field plate 39 is disposed right above the gate electrode 37 finger, with an extension part 391 extending toward the drain electrode 36. To connect the gate and the field plate 39 electrically, a contact hole 381 on the dielectric film 38 is etched down to the gate electrode 37 before overlaying the field plate 39 thereon. In the present invention, the contact hole 381 is located outside the areas of gate finger, which considerably eliminates the fabrication difficulty of aligning the contact hole 381 on the narrow gate finger electrode.

The advantage of the approach disclosed in the present invention is multifold, as comparing with the conventional Schottky gate FET with dielectric assisted field plate gate. Fist of all, the plasma damages resulted from plasma etching of dielectrics on the recess region are eliminated because no plasma etching is need for gate formation. Secondly, unpassivated areas created during gate recess next to gates are eliminated because passivation is performed after gate etch and metallization. Consequently, both performance and reliability are improved.

When implementing the invention, the thickness of the dielectric film 38 under the extension part 391 of the field plate 39 is set such that the electric field strength right underneath can modify the electric field distribution in the channel layer 32 near the edge of the gate finger and prevent junction breakdown between the gate electrode 37 and drain electrode 36.

To sum up, according to the description and drawings disclosed herein, the present invention can achieve the expected objectives. It is new and useful, and applicable in semi-conductor industry.

What is claimed is:

1. A field effect transistor with novel field-plate structure, comprising
a semiconductor substrate and a channel layer thereon;
a contact layer forming a source region, a drain region with a distance apart from said source region and a recess region being formed by removing part of said contact layer between said source and said drain regions;
a source electrode being formed on said source region, making an ohmic contact with said contact layer and being electrically coupled to said channel layer underneath;
a drain electrode being formed on said drain region, making an ohmic contact with said contact layer and being electrically coupled to said channel layer underneath;
a gate electrode having a finger shape, being formed on said recess region of said contact layer, and forming a Schottky contact with said channel layer underneath;
a dielectric film overlaying the region between said source electrode and drain electrode, including said gate electrode finger; and
an electrically conductive field plate being disposed on said dielectric film right above said gate electrode finger.

2. The field effect transistor with novel field-plate structure as described in clam 1, wherein said field plate and said gate electrode are electrically connected to each other via a contact hole on said dielectric film.

3. The field effect transistor with novel field-plate structure as described in clam 2, wherein said contact hole on said dielectric film is located at a region outside the finger areas of said gate electrode.

4. The field effect transistor with novel field-plate structure as described in clam 1, wherein said field plate is wider than said gate electrode finger, having an extension part extending toward the drain side of said gate electrode finger and being separated from the said channel layer by said dielectric film.

5. The field effect transistor with novel field-plate structure as described in clam 4, wherein the thickness of said dielectric film under said extension part of said field plate is set such that the electric field strength right underneath can modify the electric field distribution in said channel layer near the edge of said gate finger and prevent junction breakdown between said gate and said drain electrodes.

6. The field effect transistor with novel field-plate structure as described in clam 1, wherein said semiconductor substrate is a kind of III-V materials.

7. The field effect transistor with novel field-plate structure as described in clam 1, wherein said channel layer is conductive, and the conductive carriers (electrons or holes) therein are provided either by direct doping in said channel or by modulation doping.

8. The field effect transistor with novel field-plate structure as described in clam 1, wherein said dielectric film is made of silicon nitride, silicon dioxide, silicon oxynitride or other insulating dielectric materials.
